(19) United States
(12) Patent Application Publication
(10) Pub. No.: US 2007/0259533 A1
(43) Pub. Date: Nov. 8, 2007

(54) Semiconductor device and method for fabricating the same

(75) Inventors: Hyun Ahn, Kyoungki-do (KR); Jeong-Hoon Park, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/580,445

(22) Filed: Oct. 13, 2006

(30) Foreign Application Priority Data
May 2, 2006 (KR) 2006-0039709

(51) Int. Cl. H01L 23/58

(52) U.S. Cl. 438/778; 438/769; 257/635

(57) ABSTRACT

A semiconductor device includes: a structure comprising at least two heterogeneous layers having different stress levels; and a stress relief layer disposed between the two heterogeneous layers to relive a difference in the stress levels. The stress relief layer may include: a first layer formed over a first heterogeneous layer; a second layer formed over the first layer; and a third layer formed between the second layer and a second heterogeneous layer.

### FIELD OF THE INVENTION

The present invention relates to a method for fabricating a semiconductor device; and more particularly, to a semiconductor device including heterogeneous layers comprising different materials and a method for fabricating the same.

### DESCRIPTION OF RELATED ARTS

Typically, an oxide layer and a nitride layer are used as an inter-layer insulation layer of a semiconductor memory device. For instance, during forming a capacitor of the semiconductor device, a high density plasma (HDP) oxide layer is formed between bit lines and over the bit lines through a chemical vapor deposition (CVD) method, and the nitride layer is formed over the HDP oxide layer as an etch stop layer.

The oxide layer and the nitride layer include different materials. The oxide layer has a high compressive stress level and the nitride layer has a high tensile stress level. Accordingly, there is a large difference between the stress levels of the oxide layer and the nitride layer.

FIG. 1 is a micrographic image of scanning electron microscopy (SEM) illustrating exfoliation generated between an oxide layer and a nitride layer during forming a typical semiconductor device.

If a subsequent thermal treatment process is performed, the exfoliation ‘E’ may be generated around a cruspidal portion where the difference between the stress level of the oxide layer 10 and that of the nitride layer 11 is the most serious. If the exfoliation E is generated between the aforementioned heterogeneous layers, a bridge phenomenon may be induced between neighboring metal contacts as a metal interconnection material is filled in a region where the exfoliation ‘E’ is generated during forming subsequent metal interconnection lines. Accordingly, reliability of the device may be degraded.

### SUMMARY OF THE INVENTION

It is, therefore, an object of the present invention to provide a semiconductor device capable of improving reliability of a semiconductor device by reducing exfoliation generated between heterogeneous layers due to different stress levels thereof, and a method for fabricating the same.

In accordance with one aspect of the present invention, there is provided a semiconductor device, including: a structure comprising at least two heterogeneous layers having different stress levels; and a stress relief layer disposed between the two heterogeneous layers to relieve a difference in the stress levels.

In accordance with another aspect of the present invention, there is provided a semiconductor device, including: a structure comprising a first heterogeneous layer and a second heterogeneous layer formed on the first heterogeneous layers including a material having a different stress level from the first heterogeneous layer; and a stress relief layer disposed between the first heterogeneous layer and the second heterogeneous layer, and having a stress level less than the first heterogeneous layer and the second heterogeneous layer to relieve a difference in the stress levels between the first heterogeneous layer and the second heterogeneous layer.

In accordance with a further aspect of the present invention, there is provided a method for fabricating a semiconductor device, including: forming a first heterogeneous layer; forming a stress relief layer having a stress level less than the first heterogeneous layer over the first layer; and forming a second heterogeneous layer having a different stress level from the first heterogeneous layer over the stress relief layer.

### BRIEF DESCRIPTION OF THE DRAWINGS

The above and other objects and features of the present invention will become better understood with respect to the following description of the exemplary embodiments given in conjunction with the accompanying drawings, in which:

FIG. 1 is a micrographic image of scanning electron microscopy (SEM) illustrating exfoliation generated between two different kinds of layers during forming a typical semiconductor device;

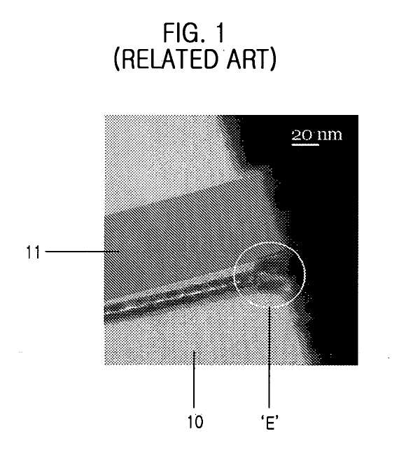

FIG. 2 is a micrographic image of SEM illustrating a semiconductor device in accordance with an embodiment of the present invention; and

FIG. 3 is a cross-sectional view illustrating the semiconductor device shown in FIG. 2.

### DETAILED DESCRIPTION OF THE INVENTION

Hereinafter, detailed descriptions on certain embodiments of the present invention will be provided with reference to the accompanying drawings. Herein, the thickness of layers and regions may be magnified in the accompanying drawings to clearly show the layers and the regions. Also, when a layer is described to be formed over the other layer or a substrate, either the layer can be directly formed on the other layer or the substrate, or a third layer may be disposed therebetween. Furthermore, the same or like reference numerals denote the same or like constitution elements even in different drawings.

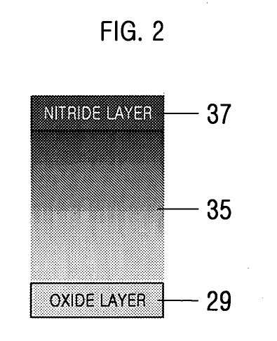

FIG. 2 is a micrographic image of scanning electron microscopy (SEM) illustrating a semiconductor device in accordance with an embodiment of the present invention. For the sake of convenience, an inter-layer insulation layer comprised of an oxide layer 29 and a nitride layer 37 is illustrated.

A stress relief layer 35 is formed between the oxide layer 29 having compressive stress and the nitride layer 37 having tensile stress. The stress relief layer 35 can be formed with a single layer or a stack layer including at least two layers to relieve different stress levels of the oxide layer 29 and the nitride layer 37.

In case of forming the stress relief layer 35 with the single layer, the stress relief layer 35 includes a material having half of the compressive stress level of the oxide layer 29 and half of the tensile stress level of the nitride layer 37. That is, the stress relief layer 35 includes a material mixed in a ratio of approximately 1 part of the oxide layer 29 and, approximately 1 part of the nitride layer 37, i.e., approximately 50 percent of the oxide layer 29 and approximately 50 percent of the nitride layer 37.

Furthermore, in case of forming the stress relief layer 35 by stacking three layers, a lower layer thereof contacting the oxide layer 29 has two thirds of the compressive stress level of the oxide layer 29 and one third of the tensile stress level of the nitride layer 37; a middle layer thereof has half of the compressive stress level of the oxide layer 29 and half of the tensile stress level of the nitride layer 37; and an upper layer thereof contacting the nitride layer 37 has one third of the compressive stress level of the oxide layer 29 and two thirds of the tensile stress level of the nitride layer 37. That is, the lower layer of the stress relief layer 35 includes a material mixed in a ratio of approximately 3 parts of the oxide layer 29 to approximately 1 part of the nitride layer 37, i.e., a ratio of approximately 75 percent of the oxide layer 29 to approximately 25 percent of the nitride layer 37. The middle layer of the stress relief layer 35 includes a material mixed in a ratio of approximately 1 part of the oxide layer 29 to approximately 1 part of the nitride layer 37, i.e., a ratio of approximately 50 percent of the oxide layer 29 to approximately 50 percent of the nitride layer 37. The upper layer of the stress relief layer 35 includes a material mixed in a ratio of approximately 1 part of the oxide layer 29 to approximately 3 parts of the nitride layer 37, i.e., a ratio of approximately 25 percent of the oxide layer 29 to approximately 75 percent of the nitride layer 37.

As described above, if the stress relief layer 35 is formed by stacking a plurality of layers, e.g., at least three layers, a first layer having a greater compressive stress level is disposed close to the oxide layer 29, and a third layer having a greater tensile stress level is disposed close to the nitride layer 37. A second layer disposed at a middle portion of the stress relief layer 35 has a material having half of the compressive stress level of the oxide layer and half of the tensile stress level of the nitride layer. The compressive stress level or the tensile stress level of the above described three layers forming the stress relief layer 35 can be changed linearly or exponentially close to the oxide layer 29 or the nitride layer 37.

According to this embodiment of the present invention, the difference between the stress level of the oxide layer 29 and that of the nitride layer 37 can be reduced by disposing the stress relief layer 35 between the oxide layer 29 and the nitride layer 37. Accordingly, exfoliation generated by the aforementioned difference between the stress levels can be prevented during a subsequent thermal process.

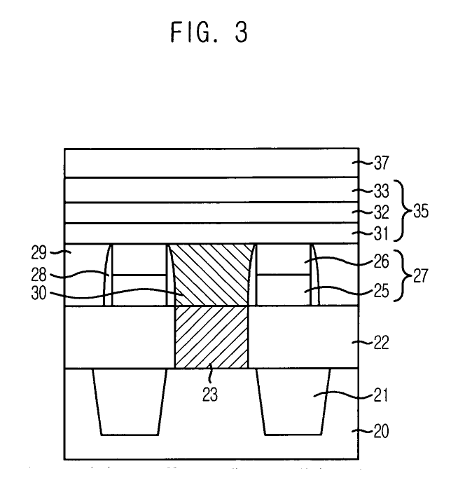

Hereinafter, the semiconductor device in accordance with the embodiment of the present invention will be applied to a dynamic random access memory (DRAM) device to be explained in detail. FIG. 3 is a cross-sectional view illustrating the nitride layer 37 serving a role as an etch stop layer over a plurality of bit lines 27 and the oxide layer 29 insulating the bit lines 27 shown in FIG. 2.

The stress relief layer 35 is disposed between the oxide layer 29 for an inter-layer insulation layer and the nitride layer 37 for an etch stop layer. The stress relief layer 35 can be formed with three layers including a lower layer 31, a middle layer 32, and an upper layer 33.

Among the three layers including the lower layer 31, the middle layer 32, and the upper layer 33, the lower layer 31 contacting the oxide layer 29 has the most similar stress level as the oxide layer 29. The middle layer 32 has a similar stress level as a composition between the oxide layer 29 and the nitride layer 37. The upper layer 33 has the most similar stress level as the nitride layer 37. A difference between the stress level of the oxide layer 29 and that of the nitride layer 37 can be reduced through the above described three layers including the lower layer 31, the middle layer 32 and the upper layer 33. Accordingly, it is possible to prevent exfoliation from being generated between the oxide layer 29 and the nitride layer 37 during a subsequent thermal treatment process.

The lower layer 31 includes a material having the most similar composition as the oxide layer 29 and the most similar stress level as the oxide layer 29. The lower layer 31 can be formed of silane (SiN₄) and nitrogen oxide (N₂O) mixed in a ratio of approximately 1:10 or greater. That is, a flow rate of N₂O is approximately 10 times greater than that of SiN₄. For example, the lower layer 31 can be formed by using SiH₄ at a flow rate of approximately 270 sccm, N₂O at a flow rate of approximately 7,700 sccm; and nitrogen N₂ at a flow rate of approximately 3,000 sccm. In this example, assuming that the flow rate of SiH₄ is approximately 1, the flow rate of N₂O which is a gas to form the oxide layer 29 sufficiently exceeds the flow rate of SiH₄ by approximately 10 times or greater. Hence, the lower layer 31 can have the most similar composition as the oxide layer 29.

The middle layer 32 includes a material having a similar composition as a composition between the oxide layer 29 and the nitride layer 37 to have a similar stress level as the composition between the oxide layer 29 and the nitride layer 37. The lower layer 32 can be formed of silane (SiN₄) and nitrogen oxide (N₂O) mixed in a ratio of approximately 1:1-9. For example, the middle layer 32 can be formed using SiH₄ at a flow rate of approximately 70 sccm, N₂O at a flow rate of approximately 180 sccm, and nitrogen N₂ or helium (He) at a flow rate of approximately 2,200 sccm. In this example, assuming that the flow rate of SiH₄ is approximately 1, the flow rate of N₂O which is the gas to form the oxide layer 29 is reduced compared with the flow rate of N₂O required to form the lower layer 31 and thus, becomes approximately 2.5 times greater than the flow rate of SiH₄. Hence, the middle layer 32 has a similar composition as silicon oxynitride (SiON) used as an anti-reflective coating layer.

The upper layer 33 includes a material having the most similar composition as the nitride layer 37 and the most similar stress level as the nitride layer 37. The upper layer 33 can be formed by adding ammonia (NH₃) into SiH₄ and N₂O mixed in a ratio of approximately 1:1 or less. Herein, a flow rate of N₂O is less than the flow rate of SiH₄ by at least one fold. Furthermore, a ratio of SiH₄ to NH₃ is controlled in a ratio of approximately 1:1-8 or approximately 1:8 or greater. That is, a flow rate of NH₃ is controlled by approximately 8 times greater than the flow rate of SiH₄. For example, the upper layer 33 is formed by injecting SiH₄ at a flow rate of approximately 140 sccm, N₂O at a flow rate of approximately 100 sccm, NH₃ at a flow rate of approximately 140 sccm and N₂ or He at a flow rate of approximately 2,200 sccm. Accordingly, assuming that the flow rate of SiH₄ is approximately 1, the flow rate of N₂O is reduced by at least one fold or less than the flow rate of SiH₄ and thus, the upper layer 33 is a composition which has a high ratio of amorphous silicon. Also, since the ratio of SiH₄ to NH₃ is the ratio of approximately 1:1-8 or approximately 1 to approximately 8 or greater, the upper layer 33 has a similar composition as the nitride layer 37.

Meanwhile, the nitride layer 37 is formed over the stress relief layer 35 by using one selected from a group consisting of a high temperature plasma enhanced chemical vapor deposition (PECVD) method, a low temperature PECVD, and a low pressure chemical vapor deposition (LPCVD). For instance, in case of forming the nitride layer 37 in the same chamber as the stress relief layer 35 in-situ, the nitride layer 37 can be formed by stopping the injection of N₂O after the upper layer 33 is formed.

The oxide layer 29 includes an undoped silicate glass (USG) layer having a composition based on SiH₄.

Reference numerals 20, 21, 22, 23, 25, 26, 27, 28, and 30 denote a substrate, a device isolation layer, an inter-layer insulation layer, a landing plug, a conductive layer, a hard mask, a bit line, spacers, and a storage node contact plug, respectively.

Although only the stress relief layer 35 formed with the single layer or the stack structure of the three layers including the lower layer 31, the middle layer 32, and the upper layer 33 is exemplified in this embodiment of the present invention, the stress relief layer 35 can be formed by stacking more than four layers. In this case, a first layer contacting the oxide layer 29 is formed under the similar condition as the lower layer 31. Until a fourth layer contacting the nitride layer 37 is formed, the flow rate of N₂O is continuously reduced to become the ratio of SiH₄ to N₂O approximately 1:1-0.1. That is, the flow rate of N₂O is reduced as close to the fourth layer from the first layer to make the stress level of the corresponding layer more similar to the nitride layer 37 than the oxide layer 29. The fourth layer is formed under the similar condition as the upper layer 33. That is, during forming the fourth layer, ammonia (NH₃) is additionally injected and thus, a mixing ratio of SiH₄ to NH₃ becomes approximately 1:1-8 or approximately 1 to approximately 8 or greater. Accordingly, the fourth layer has a similar composition as the nitride layer 37.

Furthermore, although heterogeneous layers including an oxide layer and a nitride layer are exemplified in this embodiment of the present invention, any other kinds of heterogeneous layers formed by stacking materials having different stress levels under a certain condition (e.g., heat) can be used in this embodiment of the present invention.

As described above, the following effects can be obtained. A stress relief layer which relieves different stress levels of heterogeneous layers is formed and thus, a cruspidal portion where the difference between the stress levels of the heterogeneous layers is the greatest can be removed. Accordingly, exfoliation generated between the heterogeneous layers can be prevented during a subsequent thermal process, thereby improving reliability of the device.

Also, a process of forming a stress relief layer is performed before a deposition process of a nitride layer. That is, a separate process is not added. Thus, different stress levels of heterogeneous layers can be relieved without increasing cost and time. Accordingly, it is possible to obtain an economical effect.

The present application contains subject matter related to the Korean patent application No. KR 2006-0039709, filed in the Korean Patent Office on May 2, 2006, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A semiconductor device, comprising:
a structure comprising at least two heterogeneous layers having different stress levels; and
a stress relief layer disposed between the two heterogeneous layers to relieve a difference in the stress levels.

2. The semiconductor device of claim 1, wherein the stress relief layer has a stress level less than the individual heterogeneous layers.

3. The semiconductor device of claim 2, wherein the stress relief layer is formed with one of a single layer and a stack structure comprising at least two layers.

4. The semiconductor device of claim 2, wherein the stress relief layer includes a material having a stress level that is half of the stress level of the individual heterogeneous layers.

5. The semiconductor device of claim 2, wherein the stress relief layer includes:
a first layer formed over a first heterogeneous layer;
a second layer formed over the first layer; and
a third layer formed between the second layer and a second heterogeneous layer, wherein a stress level increases to the stress level of the second heterogeneous layer going from the first layer to the third layer, and a stress level increases to the stress level of the first heterogeneous layer going from the third layer to the first layer.

6. The semiconductor device of claim 2, wherein the heterogeneous layers comprise an oxide layer and a nitride layer.

7. The semiconductor device of claim 6, wherein the stress relief layer has half of the stress level of the oxide layer and half of the stress level of the nitride layer.

8. The semiconductor device of claim 6, wherein the stress relief layer comprises a mixture layer of an oxide-based material and a nitride-based material.

9. The semiconductor device of claim 6, wherein the stress relief layer includes:
a first layer formed over the oxide layer;
a second layer formed over the first layer; and
a third layer formed between the second layer and the nitride layer, wherein a stress level increases to the stress level of the nitride layer going from the first layer to the third layer, and a stress level increases to the stress level of the oxide layer going from the third layer to the first layer.

10. The semiconductor device of claim 9, wherein a compressive stress level of the first layer is greater than the second layer and the third layer, and a tensile stress level of the first layer is less than the second layer and the third layer.

11. The semiconductor device of claim 9, wherein a compressive stress level of the third layer is less than the first layer and the second layer, and a tensile stress level of the third layer is greater than the first layer and the second layer.

12. The semiconductor device of claim 9, wherein a compressive stress level of the second layer is substantially the same as a tensile stress level of the second layer.

13. A semiconductor device, comprising:
a structure comprising a first heterogeneous layer and a second heterogeneous layer formed on the first heterogeneous layers including a material having a different stress level from the first heterogeneous layer; and
a stress relief layer disposed between the first heterogeneous layer and the second heterogeneous layer, and having a stress level less than the first heterogeneous layer and the second heterogeneous layer to relieve a difference in the stress levels between the first heterogeneous layer and the second heterogeneous layer.

14. The semiconductor device of claim 13, wherein the stress relief layer comprises a plurality of layers, wherein a layer close to the first heterogeneous layer includes a material having substantially the same stress level as the first heterogeneous layer and a layer close to the second heterogeneous layer includes a material having substantially the same stress level as the second heterogeneous layer.

15. A method for fabricating a semiconductor device, comprising:
forming a first heterogeneous layer;
forming a stress relief layer having a stress level less than the first heterogeneous layer over the first layer; and
forming a second heterogeneous layer having a different stress level from the first heterogeneous layer over the stress relief layer.

16. The method of claim 15, wherein the first heterogeneous layer, the stress relief layer and the second heterogeneous layer are formed in-situ.

17. The method of claim 16, wherein the first heterogeneous layer includes an oxide layer, and the second heterogeneous layer includes a nitride layer.

18. The method of claim 17, wherein the stress relief layer includes a mixture including an oxide-based material and a nitride-based material.

19. The method of claim 17, wherein the forming of the stress relief layer includes:
forming a first layer over the oxide layer;
forming a second layer over the first layer; and
forming a third layer over the second layer.

20. The method of claim 19, wherein the forming of the first layer is performed using a gas mixture including silane (SiH₄), nitrogen oxide (N₂O), and nitrogen (N₂) at a flow rate of N₂O being approximately 10 times greater than the flow rate of SiH₄.

21. The method of claim 20, wherein the forming of the first layer is performed injecting SiH₄ at a flow rate of approximately 270 sccm, N₂O at a flow rate of approximately 7,700 sccm, and N₂ at a flow rate of approximately 3,000 sccm.

22. The method of claim 20, wherein the forming of the second layer is performed using a gas mixture including SiH₄, N₂O, and N₂, and a ratio of SiH₄ to N₂O is controlled in a ratio of approximately 1:1-9.

23. The method of claim 22, wherein the forming of the second layer is performed injecting one of a gas mixture including SiH₄, N₂O and N₂, and another gas mixture including SiH₄, N₂O and helium (He), SiH₄ having a flow rate of approximately 70 sccm, N₂O having a flow rate of approximately 180 sccm, N₂ having a flow rate of approximately 2,200 sccm, and He having a flow rate of approximately 2,200 sccm.

24. The method of claim 20, wherein the second layer includes silicon oxynitride (SiON).

25. The method of claim 22, wherein the forming of the third layer is performed using one of a gas mixture including SiH₄, N₂O, ammonia (NH₃), and N₂, and another gas mixture including SiH₄, N₂O, NH₃, and He, wherein a flow rate of N₂O is less than the flow rate of SiH₄ by at least one fold and a flow rate of NH₃ is approximately 8 times greater than the flow rate of SiH₄.

26. The method of claim 25, wherein the forming of the third layer is performed injecting one of a gas mixture including SiH₄, N₂O, NH₃ and N₂, and another gas mixture including SiH₄, N₂O, NH₃ and He, SiH₄ having a flow rate of approximately 140 sccm, N₂O having a flow rate of approximately 100 sccm, NH₃ having a flow rate of 140 sccm, N₂ having a flow rate of approximately 2,200 sccm and He having a flow rate of approximately 2,200 sccm.

27. The method of claim 25, wherein the nitride layer is formed through one of a plasma enhanced chemical vapor deposition (PECVD) method and a low pressure chemical vapor deposition (LPCVD) method.

28. The method of claim 25, wherein the nitride layer is formed by stopping the injection of N₂O after the third layer is formed.

29. The method of claim 28, wherein the oxide layer includes undoped silicate glass (USG) layer having a composition based on SiH₄.
